(19) United States
(12) Patent Application Publication
(10) Pub. No.: US 2015/0255430 A1
(43) Pub. Date: Sep. 10, 2015

(54) PACKAGE STRUCTURE

(71) Applicant: UNITED MICROELECTRONICS CORP., Hsin-Chu City (TW)

(72) Inventor: Kuang-Hui Tang, Kaohsiung City (TW)

(73) Assignee: UNITED MICROELECTRONICS CORP., Hsin-Chu City (TW)

(21) Appl. No.: 14/201,934

(22) Filed: Mar. 10, 2014

(51) Int. Cl. H01L 25/065; H01L 23/00; H01L 23/522

(52) U.S. Cl. CPC H01L 25/0657; H01L 23/5226; H01L 24/06; H01L 24/14; H01L 2224/0612; H01L 2224/1405; H01L 2225/06541; H01L 2225/06513; H01L 2225/06555; H01L 2224/16057; H01L 2224/16113; H01L 2224/16146

(57) ABSTRACT

A package structure is disclosed. The package structure includes a first die, a second die on the first die, and a substrate disposed corresponding to the first die. The first die includes a first die identification (ID) region defined thereon and a plurality of first through silicon vias (TSVs) in the first die ID region. The second die includes another first die identification (ID) region and a second die ID region defined thereon and a plurality of second TSVs in the another first die ID region and a plurality of third TSVs in the second die ID region, in which the second TSVs are electrically connected to the first TSVs in the first die.

### BACKGROUND OF THE INVENTION

1. Field of the Invention

The invention relates to a package structure, and more particularly to a package structure with embedded through-silicon vias for determining die identification of each die.

2. Description of the Prior Art

In company with the development of fabrication technology, the current integrated circuits have higher complexity and smaller size compared to the conventional integrated circuits. Therefore, a flip-chip package technology with relatively high integration density and relatively more input/output pins has been developed. The flip-chip package is a technology that can connect semiconductor elements, such as a die chip being processed and diced from a semiconductor wafer to external circuits. The aforementioned external circuits may include package carriers or printed circuit boards.

Compared to the other packaging technologies, the merits of the flip-chip package technology include more area for input/output connections, reaching relatively high transmission rates with relatively little interference, and preventing interference from the external environmental factors.

Typically, die identification (ID) providing information to the specific location of each die relative to the wafer is required during a yield improvement analysis. However, conventional fabrication process after package structures being fabricated provides no means whatsoever for generating die ID for each die. Instead, die IDs providing information to each die's specific location relative to the wafer needs to be written manually by the packaging facilities, which not only delays cycle time but also results in frequent errors.

### SUMMARY OF THE INVENTION

It is therefore an objective of the present invention to provide a novel package structure for resolving the aforementioned issues.

According to a preferred embodiment of the present invention, a package structure is disclosed. The package structure includes a first die, a second die on the first die, and a substrate disposed corresponding to the first die. The first die includes a first die identification (ID) region defined thereon and a plurality of first through silicon vias (TSVs) in the first die ID region. The second die includes another first die identification (ID) region and a second die ID region defined thereon and a plurality of second TSVs in the another first die ID region and a plurality of third TSVs in the second die ID region, in which the second TSVs are electrically connected to the first TSVs in the first die.

According to another aspect of the present invention, a package structure having a first die, a second die on the first die, and a substrate disposed corresponding to the first die is disclosed. The first die includes a first die identification (ID) region defined thereon and a plurality of first through-silicon vias (TSVs) in the first die ID region, in which the first TSVs are exposed from a backside of the first die. The second die includes a second die ID region defined thereon and a plurality of second TSVs in the second die ID region, in which the second TSVs are exposed from a backside of the second die.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a package structure according to a first embodiment of the present invention.

FIG. 2 is a perspective view illustrating a package structure according to a second embodiment of the present invention.

FIG. 3 is a perspective view illustrating a package structure according to an embodiment of the present invention.

FIGS. 4-5 are perspective views illustrating package structures according to additional embodiments of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Referring to FIGS. 1, FIG. 1 is a perspective view illustrating a package structure according to a first embodiment of the present invention. As shown in FIG. 1, the package structure preferably includes a first die 12, a second die 14, and a substrate 16, in which the first die 12 and the second die 14 are equivalent in size, the second die 14 is disposed on top of the first die 12, and the substrate 16 is disposed corresponding to the first die 12.

According to an embodiment of the present invention, each of the first die 12 and the second die 14 may be a fragment obtained from a silicon wafer that has been diced and processed to include all of the interconnections necessary, the dies could be connected by reflowed solders 17, and the substrate 16 may be a printed circuit board or any other packaging substrate, but not limited thereto.

According to a preferred embodiment of the present invention, a first die identification (ID) region 18 is defined on the first die 12 and a plurality of first through silicon vias (TSVs) 20 are formed in the first die ID region 18. The TSVs 20 may be formed by any known TSV fabrication processes, and as such processes are well known to those skilled in the art, the details of which are not explained herein for the sake of brevity.

Another first die ID region 18 and a second die ID region 22 are defined on the second die 14, a plurality of second TSVs 24 are formed in the another first die ID region 18 and a plurality of third TSVs 26 are formed in the second die ID region 22 of the second die 14.

Preferably, the second TSVs 24 formed in the another first die ID region 18 of the second die 14 are electrically connected to the first TSVs 20 formed in the first die ID region 18 of the first die 12 so that information corresponding to a die ID of the first die 12 could be transferred to the second die 14.

As the another first die ID region 18 and the second die ID region 22 are both defined on a backside of the second die 14, and also that the second TSVs 24 and third TSVs 26 are exposed from the backside of the second die 14, a die ID corresponding to each die could be generated by electrically testing whether electrical connections are established through the exposed TSVs 24 and 26 according to a binary system.

For instance, if no electrical connection is tested at an exposed TSV, such as the middle TSVs in the first region 18 of the first die 12 and the second die 14, a die ID of zero would be assigned whereas if an electrical connection is tested at an exposed TSV, a die ID of one would be assigned. By acquiring the die ID in this manner in relation to a binary system, the location of each die relative to the entire wafer could be determined accordingly.

The package structure also includes a plurality of first bump pads 28 on a first surface 30 of the substrate 16, a plurality of second bump pads 32 on a front side of the first die 12, and a plurality of bumps 34 between and contact the first bump pads 28 and the second bump pads 32.

A plurality of solder pads 36 are also formed on a second surface 38 of the substrate 16 and a plurality of solder balls 40 are mounted on the solder pads 36, in which the solder balls 40 are electrically connected to the first bump pads 28 situating on the first surface 30 of the substrate 16.

It should be noted that instead of stacking only two dies for forming the package structure, additional dies could be stacked on top of the second die, which is also within the scope of the present invention. Preferably, the size of each die stacked on top of the second die is equivalent to the second die and the first die, and the quantity of the dies constituting the package structure could also be adjusted according to the demand of the product.

In addition, the die stacked on top would include a set of TSVs connecting to the die below so that the information corresponding to the die below could be passed to the die above. For instance, if a third die (not shown) were stacked on top of the second die 14, a third die ID region in addition to another first die ID region and another second die ID region would be defined on the third die. The die ID regions would also include a set of TSVs in the third die ID region carrying die ID information solely for the third die, a set of TSVs in the second die ID region connected to the third TSVs 26 in the second die ID region 22 of the second die 14, and a set of TSVs in the first die ID region connected to the second TSVs 24 in the first die ID region 18 of the second die 14.

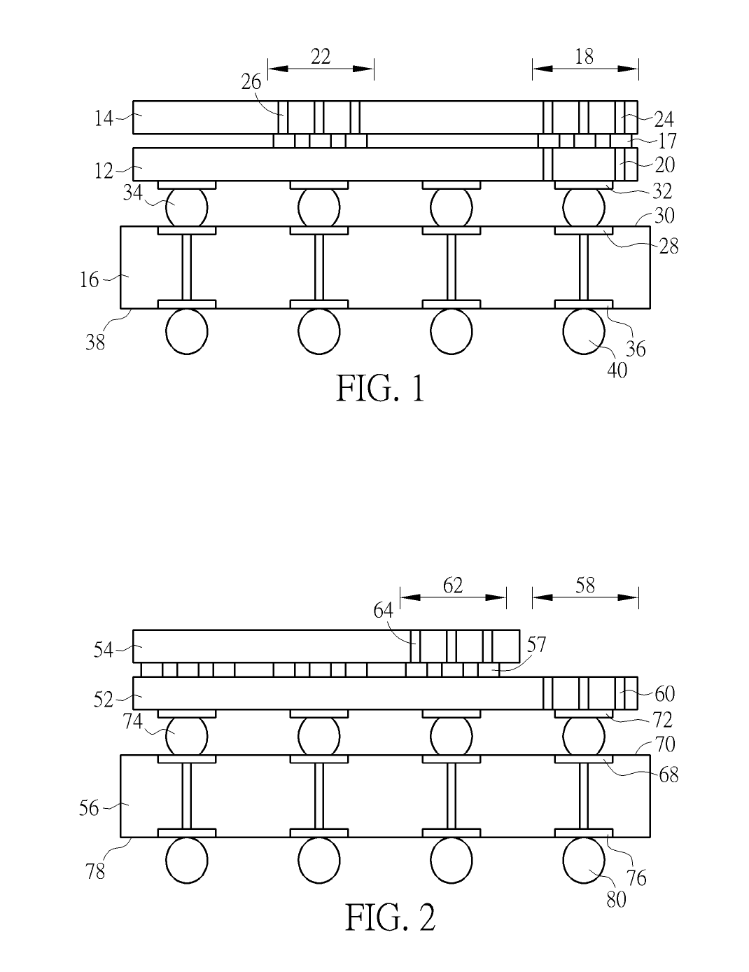

Referring to FIGS. 2, FIG. 2 is a perspective view illustrating a package structure according to a second embodiment of the present invention. As shown in FIG. 2, the package structure preferably includes a first die 52, a second die 54, and a substrate 56, in which the second die 54 is disposed on top of the first die 52, the first die 52 is larger in size than the second die 54, and the substrate 56 is disposed corresponding to the first die 52.

Similar to the aforementioned embodiment, each of the first die 52 and the second die 54 may be a fragment obtained from a silicon wafer that has been diced and processed to include all of the interconnections necessary, the dies may be connected by reflowed solders 57, and the substrate 56 may be a printed circuit board or any other packaging substrate.

Preferably in this embodiment, a first die identification (ID) region 58 is defined on the first die 52 and a plurality of first through silicon vias (TSVs) 60 are formed in the first die ID region 58, in which the first TSVs 60 are preferably exposed from a backside of the first die 52. The TSVs 60 may be formed by any known TSV fabrication processes, and as such processes are well known to those skilled in the art, the details of which are not explained herein for the sake of brevity.

A second die ID region 62 is defined on the second die 54 and a plurality of second TSVs 64 are formed in the second die ID region 62, in which the second TSVs 64 are exposed from a backside of the second die 54.

It should be noted that as the defined first die ID region 58 is not blocked by the second die ID region 62 so that the exposed first TSVs 60 in the first die ID region 58 are also not blocked by the second TSVs 64 in the second die ID region 62, a die ID for each die may be generated by visually examining the exposed TSVs 60 and 64 in each die region in accordance with a binary system. For instance, if a TSV is present, a die ID of one could be assigned, whereas if no TSV is present, a die ID of zero could be assigned. By acquiring the die ID in this manner, the location of each die relative to the entire wafer could be determined accordingly.

Similar to the aforementioned embodiment, instead of visually examining the exposed TSVs for determining the die IDs, the die IDs in this embodiment could also be acquired by electrically testing whether an electrical connection is established in the exposed TSVs according to a binary system.

The package structure also includes a plurality of first bump pads 68 on a first surface 70 of the substrate 56, a plurality of second bump pads 72 on a front side of the first die 52, and a plurality of bumps 74 between and contact the first bump pads 68 and the second bump pads 72.

A plurality of solder pads 76 are also formed on a second surface 78 of the substrate 56 and a plurality of solder balls 80 are mounted on the solder pads 76, in which the solder balls 80 are electrically connected to the first bump pads 68 situating on the first surface 70 of the substrate 56.

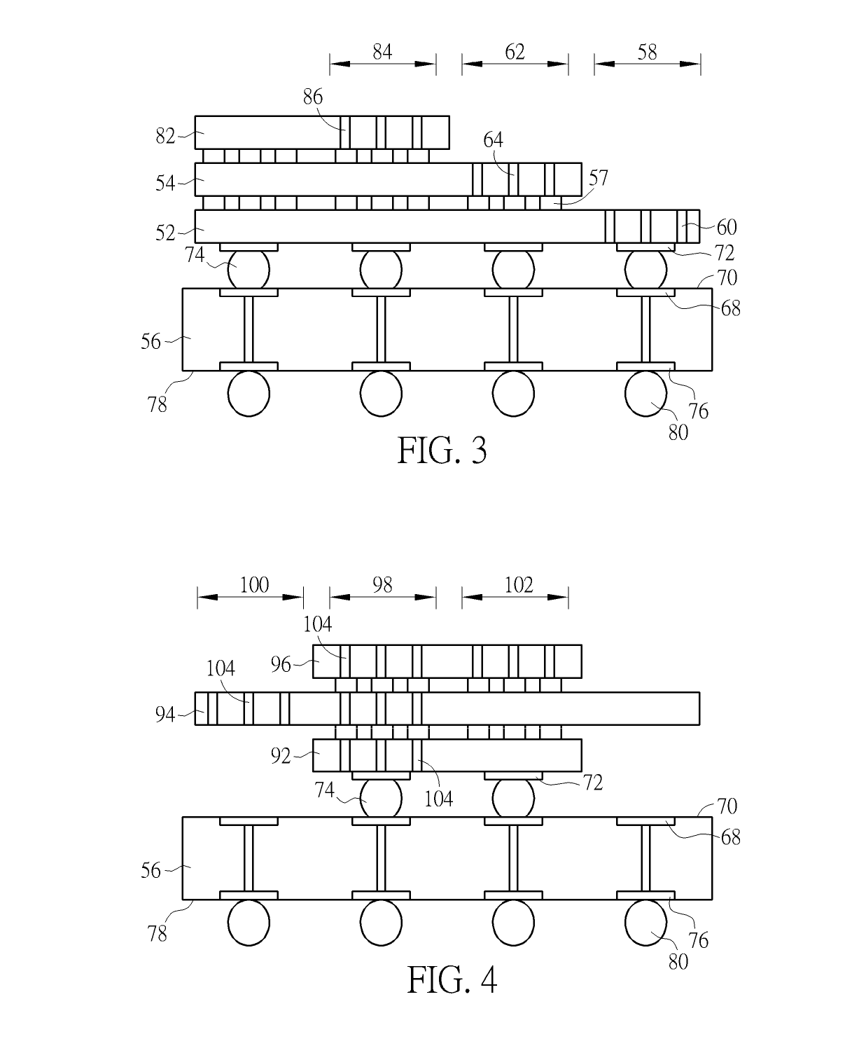

It should also be noted that instead of stacking only two dies for forming the package structure, additional dies could be stacked on top of the second die, which is also within the scope of the present invention. Preferably, the size of each die stacked on top is smaller in size than the one below, and the quantity of the dies constituting the package structure could also be adjusted according to the demand of the product. For instance, as shown in FIG. 3, a package structure having an additional third die 82 stacked on top of the second die 54 is provided.

The third die 82 is preferably smaller in size than the second die 54, and a third die ID region 84 may be defined on the third die 82 and a plurality of third TSVs 86 are formed in the third die ID region 84 within the third die 86. As the first die ID region 58 of the first die 52 and second die ID region 62 of the second die 54 are designed in regions not overlapped by the third die 82, the TSVs within the first die ID region 58 and the second die ID region 62 are preferably not blocked by the TSVs in the third die ID region 84 so that die ID of each region could be obtained by either visual examination or electrically testing as addressed in the aforementioned embodiments.

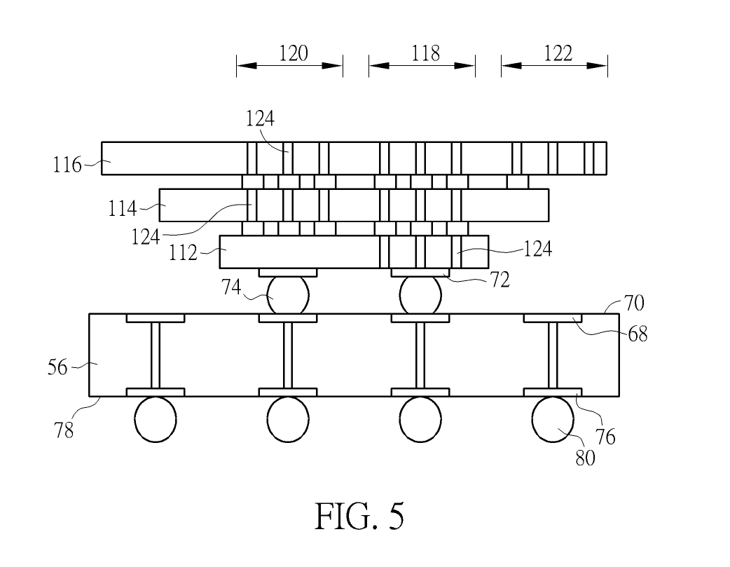

Referring to FIGS. 4-5, FIGS. 4-5 are perspective views of package structures according to additional embodiments of the present invention. As shown in FIG. 4, a package structure having a first die 92, second die 94, a third die 96, and a substrate 56 is disclosed, in which the second die 94 is preferably larger in size than the first die 92 and the third die 96. A first die ID region 98 is defined on the first die 92, the second die 94, and the third die 96, a second die ID region 100 is defined only on the second die 94, and a third die ID region 102 is only defined on the third die 96. A plurality of TSVs 104 are formed in the first die ID region 98 of the three dies, the second die ID region 100 of the second die 94, and the third die ID region 102 of the third die 96 respectively.

In this embodiment, as the first die 92 is smaller in size than the second die 94 causing that TSVs 104 in the first die 92 could not be visually examined, only electrical testing could be carried out to determine the die ID for each die.

Similar to the aforementioned embodiments, the first die 92 is connected to a substrate 56 by corresponding bump pads 68 and 72 and bumps 74, and the substrate 56 also includes a plurality of solder pads 76 and solder balls 80 connecting to the bump pads 68. As the arrangement of these elements is identical to the aforementioned embodiments, the details of which are omitted herein for the sake of brevity.

As shown in FIG. 5, a package structure having a first die 112, second die 114, a third die 116, and a substrate 56 is disclosed, in which the third die 116 is preferably larger in size than the first die 112 and the second die 114. A first die ID region 118 is defined on the first die 112, the second die 114, and the third die 116, a second die ID region 120 is defined on the second die 114 and the third die 116, and a third die ID region 122 is only defined on the third die 116. A plurality of TSVs 124 are formed in the first die ID region 118 of the three dies, the second die ID region 120 of the second die 114 and the third die 116, and the third die ID region 122 of the third die 116 respectively.

In this embodiment, as the first die 112 and the second die 114 are both smaller in size than the third die 116 causing that TSVs 124 in the first die 112 and the second die 114 could not be visually examined, only electrical testing could be carried out to determine the die ID for each die.

Similar to the aforementioned embodiments, the first die 112 is connected to a substrate 56 by corresponding bump pads 68 and 72 and bumps 74, and the substrate 56 also includes a plurality of solder pads 76 and solder balls 80 connecting to the bump pads 68. As the arrangement of these elements is identical to the aforementioned embodiments, the details of which are omitted herein for the sake of brevity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A package structure, comprising:
a first die, comprising a first die identification (ID) region defined thereon and a plurality of first through silicon vias (TSVs) in the first die ID region;
a second die on the first die, wherein the second die comprises another first die identification (ID) region and a second die ID region defined thereon and a plurality of second TSVs in the another first die ID region and a plurality of third TSVs in the second die ID region, wherein the second TSVs are electrically connected to the first TSVs in the first die; and
a substrate disposed corresponding to the first die.

2. The package structure of claim 1, wherein the another first die ID region and the second die ID region are defined on a backside of the second die.

3. The package structure of claim 2, wherein the second TSVs and third TSVs are exposed from the backside of the second die.

4. The package structure of claim 1, wherein the first die and the second die are equivalent in size.

5. The package structure of claim 1, wherein the substrate comprises:
a plurality of first bump pads on a first surface of the substrate; and
a plurality of solder balls on a second surface of the substrate and electrically connected to the first bump pads.

6. The package structure of claim 5, further comprising a plurality of second bump pads on a front side of the first die and a plurality of bumps between and contact the first bump pads and the second bump pads.

7. A package structure, comprising:
a first die, comprising a first die identification (ID) region defined thereon and a plurality of first through-silicon vias (TSVs) in the first die ID region, wherein the first TSVs are exposed from a backside of the first die;
a second die on the first die, wherein the second die comprises a second die ID region defined thereon and a plurality of second TSVs in the second die ID region, wherein the second TSVs are exposed from a backside of the second die; and
a substrate disposed corresponding to the first die.

8. The package structure of claim 7, wherein the first die ID region is defined on the backside of the first die and the second die ID region is defined on the backside of the second die.

9. The package structure of claim 7, wherein the first die is larger in size than the second die.

10. The package structure of claim 7, wherein the substrate comprises:
a plurality of first bump pads on a first surface of the substrate; and
a plurality of solder balls on a second surface of the substrate and electrically connected to the first bump pads.

11. The package structure of claim 10, further comprising a plurality of second bump pads on a front side of the first die and a plurality of bumps between and contact the first bump pads and the second bump pads.
